(19) United States
(12) Patent Application Publication
(10) Pub. No.: US 2022/0231144 A1
(43) Pub. Date: Jul. 21, 2022

(54) SEMICONDUCTOR STRUCTURE, METHOD FOR MANUFACTURING THE SAME, AND TRANSISTOR

(71) Applicant: INSTITUTE OF MICROELECTRONICS, CHINESE ACADEMY OF SCIENCES, Beijing (CN)

(72) Inventors: Jun LUO, Beijing (CN); Tianchun YE, Beijing (CN); Dan ZHANG, Beijing (CN)

(21) Appl. No.: 17/214,042

(22) Filed: Mar. 26, 2021

Related U.S. Application Data
(63) Continuation of application No. PCT/CN2021/075739, filed on Feb. 7, 2021.

(30) Foreign Application Priority Data
Jan. 15, 2021 (CN) 202110055950.4

(51) Int. Cl. H01L 29/423; H01L 29/417; H01L 29/40; H01L 29/06; H01L 29/786; H01L 29/66

(52) U.S. Cl. CPC H01L 29/42392; H01L 29/41733; H01L 29/66742; H01L 29/0673; H01L 29/78696; H01L 29/401

(57) ABSTRACT

A semiconductor structure, a method for manufacturing the semiconductor structure, and a transistor. A doped structure is provided, where the doped structure includes a dopant. A surface of the doped structure is oxidized to form the oxide film. In such case, the dopant at an interface between the oxide film and the doped structure may be redistributed, and thereby a segregated-dopant layer is formed inside or at a surface of the doped structure under the oxide film. A concentration of the dopant is higher in the segregated-dopant layer than in other regions of the doped structure. After the oxide film is removed, the doped structure with a high surface doping concentration can be obtained without an additional doping process. Therefore, after a conducting structure is formed on the segregated-dopant layer, a low contact resistance between the conducting structure and the doped structure is obtained, and a device performance is improved.

The present application is a bypass continuation application of International Application No. PCT/CN2021/075739, titled “SEMICONDUCTOR STRUCTURE, METHOD FOR MANUFACTURING THE SAME, AND TRANSISTOR,” filed on Feb. 7, 2021, which claims the priority to Chinese Patent Application No. 202110055950.4, titled “SEMICONDUCTOR STRUCTURE AND METHOD FOR MANUFACTURING THE SAME,” filed on Jan. 15, 2021 with the China National Intellectual Property Administration, both of which are incorporated herein by reference in their entireties.

### FIELD

The present disclosure relates to the technical field of semiconductor devices, and in particular to a semiconductor structure, a method for manufacturing the semiconductor structure, and a transistor.

### BACKGROUND

Manufacturing semiconductor devices may concern doping an intrinsic semiconductor to obtain a doped structure, and the doped structure may be led out via a metal material. The doped structure may be, for example, a source, a drain, or a gate. There is a large resistance between the metal material and the doped structure. Shrinkage of the devices renders such resistance an increasingly important factor affecting device performances. Thus, an urgent problem to be solved in this field is how to reduce the resistance between the metal material and the doped structure.

Currently, the resistance between the metal material and the doped structure may be reduced by yielding a compound through reaction between the metal material and the doped structure. In such practice, a large contact resistance between the doped structure and the reacted compound reduces device performances.

### SUMMARY

In view of the above, an objective of the present disclosure is to provide a semiconductor structure, a method for manufacturing the semiconductor structure, and a transistor. A contact resistance between the conducting structure and the doped structure is reduced, and a device performance is improved.

A method for manufacturing a semiconductor is provided according to an embodiment of the present disclosure, including:

providing a doped structure, where the doped structure includes a dopant;

oxidizing a surface of the doped structure, to form an oxide film and a segregated-dopant layer, where the segregated-dopant layer is located inside or at a surface of the doped structure under the oxide film, and a concentration of the dopant is higher in the segregated-dopant layer than in other regions of the doped structure;

removing the oxide film, and

forming a conducting structure on the segregated-dopant layer.

In an optional embodiment, forming the conducting structure on the segregated-dopant layer includes:

forming a conducting material on the doped structure, and

annealing the doped structure and the conducting material, where the doped structure and the conducting material react in the annealing to yield a compound serving as the conducting structure.

In an optional embodiment, the conducting material includes at least one of Ni, Pt, NiPt, Co, Ti, Ta, W, Ru, Cu, CoTi, TaN, or TiN.

In an optional embodiment, before removing the oxide film, the method further includes:

activating the dopant in the segregated-dopant layer through annealing treatment, after the oxide film being formed or during the oxidizing.

In an optional embodiment, the annealing treatment includes rapid thermal annealing, microwave annealing, or laser annealing.

In an optional embodiment, the doped structure is at least one of a source structure, a drain structure, or a gate structure.

In an optional embodiment, a material of the doped structure includes Si, SiGe, or Ge.

In an optional embodiment, a thickness of the oxide film ranges from 0.5 nm to 50 nm.

A semiconductor structure is provided according to an embodiment of the present disclosure, including:

a doped structure, where the doped structure includes a dopant, a segregated-dopant layer is formed inside or at a surface of the doped structure, and a concentration of the dopant is higher in the segregated-dopant layer than in other regions of the doped structure; and

a conducting structure, located on the segregated-dopant layer.

In an optional embodiment, the conducting structure is a compound yielded from reaction between the doped structure and a conducting material.

In an optional embodiment, a material of the doped structure includes Si, SiGe, or Ge.

In an optional embodiment, the conducting material includes at least one of Ni, Pt, NiPt, Co, Ti, Ta, W, Ru, Cu, CoTi, TaN, or TiN.

A transistor is provided according to an embodiment of the present disclosure. The transistor is formed on a semiconductor substrate, and includes a gate structure, a source structure, and a drain structure. The transistor includes the forgoing semiconductor structure, of which the doped structure serves as at least one of the source structure, the drain structure, or the gate structure.

In an optional embodiment, the transistor is a MOSFET, a FinFET, or a GAAFET.

In an optional embodiment, the gate structure is located on the semiconductor substrate;

alternatively, the semiconductor substrate includes a protruding structure, and the gate structure covers a top surface and two sidewalls of the protruding structure;

alternatively, a nanowire that is horizontal or vertical is provided on the semiconductor substrate, the gate structure surrounds the nanowire, and the source structure and the drain structure are located at two ends, respectively, of the nanowire.

In an optional embodiment, the conducting structure includes a contacting region.

The semiconductor structure, the method for manufacturing the semiconductor structure, and the transistor are provided according to embodiments of the present disclosure. The doped structure is provided, where the doped structure may include a dopant. The surface of the doped structure is oxidized to form the oxide film. In such case, the dopant at the interface between the oxide film and the doped structure may be redistributed, and thereby the segregated-dopant layer is formed inside or at a surface of the doped structure under the oxide film. The concentration of the dopant is higher in the segregated-dopant layer than in other regions of the doped structure. After the oxide film is removed, the doped structure with a high surface doping concentration can be obtained without an additional doping process. Therefore, after the conducting structure is formed on the segregated-dopant layer, a low contact resistance between the conducting structure and the doped structure is obtained, and a device performance is improved.

### BRIEF DESCRIPTION OF THE DRAWINGS

For clearer illustration of the technical solutions according to embodiments of the present disclosure or conventional techniques, hereinafter briefly described are the drawings to be applied in embodiments of the present disclosure or conventional techniques. Apparently, the drawings in the following descriptions are only some embodiments of the present disclosure, and other drawings may be obtained by those skilled in the art based on the provided drawings without creative efforts.

FIG. 1 is a flow chart of a method for manufacturing a semiconductor according to an embodiment of the present disclosure;

FIG. 2 and FIG. 3 are schematic structural diagrams in a process of manufacturing a semiconductor structure according to an embodiment of the present disclosure;

FIG. 4 is a schematic diagram of a segregation phenomenon according to an embodiment of the present disclosure; and

FIG. 5, FIG. 6, and FIG. 7 are schematic structural diagrams in a process of manufacturing a semiconductor structure according to an embodiment of the present disclosure.

### DETAILED DESCRIPTION OF EMBODIMENTS

For clearness and better understanding of the above objectives, features and advantages of the present disclosure, hereinafter specific embodiments of the present disclosure are described in detail in conjunction with the drawings.

Many specific details are set forth in following description, for fully understanding the present disclosure. The present disclosure may further be implemented in a manner other than that described herein, and those skilled in the art can make similar modifications without deviating from a core of the present disclosure. Therefore, the present disclosure is not limited to the specific embodiments disclosed below.

Further, the present disclosure is described in detail in conjunction with schematic diagrams. For convenience of illustration of embodiments of the present disclosure, a cross-sectional view showing the device structure may be partially enlarged not according to a general scale. The schematic diagrams are only intended for illustration, and should not be construed as limitations to the protection scope of the present disclosure. In addition, three-dimensional dimensions, i.e. a length, a width and a depth, should be considered in practical manufacturing.

Manufacturing semiconductor devices may concern doping an intrinsic semiconductor to obtain a doped structure, and the doped structure may be led out via a metal material. The doped structure may be, for example, a source, a drain, or a gate. There is a large resistance between the metal material and the doped structure. Shrinkage of the devices renders such resistance an increasingly important factor affecting device performances. Thus, an urgent problem to be solved in this field is how to reduce the resistance between the metal material and the doped structure.

Currently, the resistance between the metal material and the doped structure may be reduced by yielding a compound through reaction between the metal material and the doped structure. In such practice, a large contact resistance between the doped structure and the reacted compound reduces device performances.

For example, in MOSFET, FinFET, GAA (Gate-all-around) devices, a metal silicide may be formed on a source structure and a drain structure, in order to reduce both a resistance between the source structure and a metallic lead-out structure and a resistance between the drain structure and a metallic lead-out structure. After a process node of CMOS technology reaches 10 nm and even smaller dimension, a gate and a channel of the devices are shrinking, and a channel resistance R_{ch} is decreasing. Thus, the source-drain parasitic resistance Rₚₐᵣₐ becomes one of the main restrictions on device performances. The source-drain parasitic resistance results in a RC delay, and advancing of the CMOS technology results in an increasing proportion of such RC delay in a total delay.

The source-drain parasitic resistance Rₚₐᵣₐ includes a spreading resistance Rₑₓₜ of a source/drain located under an isolation sidewall, and a contact resistance Re between the metal silicide and the source/drain. With shrinkage of a CPP (contacted-poly-pitch), a contact area at a source/drain region decreases drastically, and what dominates in the source-to-drain current path changes from a horizontal current to a vertical current, in comparison with conventional planar transistors. Thus, the contact resistance Re is much larger than the source-drain extension resistance Rₑₓₜ, and becomes the dominant factor in the source-drain parasitic resistance Rₚₐᵣₐ. Therefore, it is essential to reduce the contact resistance Re when implementing a high-performance transistor device.

The contact resistance Re may be expressed by a following equation.

$${R}_{c} = {C}_{1} exp ( {C}_{2} \frac{q {ϕ}_{b}}{\sqrt{N}} ) \times {Area}^{- 1} .$$

That is, there are three manners to reduce the contact resistance R_{c}. A first manner is lowering a height (ϕ_{b}) of a Schottky barrier. A second manner is increasing the contact area (Area). A third manner is increasing the surface doping concentration (N) of a doped structure. The height of the Schottky barrier relates to materials of the dopant and the metal silicide, and hence is not convenient to adjust. The contact area is limited by the CPP, and cannot be effectively increased. An increase in a surface doping concentration of the doped structure results in an additional doping process.

In view the above technical issues, a semiconductor structure and a method for manufacturing the semiconductor structure are provided according to embodiments of the present disclosure. A doped structure is provided, where the doped structure may include a dopant. A surface of the doped structure is oxidized to form the oxide film. In such case, the dopant at an interface between the oxide film and the doped structure may be redistributed, and thereby a segregated-dopant layer is formed inside or at a surface of the doped structure under the oxide film. A concentration of the dopant is higher in the segregated-dopant layer than in other regions of the doped structure. After the oxide film is removed, the doped structure with a high surface doping concentration can be obtained without an additional doping process. Therefore, after a conducting structure is formed on the segregated-dopant layer, a low contact resistance between the conducting structure and the doped structure is obtained, and a device performance is improved.

For better understanding of technical solutions and technical effects of the present disclosure, hereinafter specific embodiments are described in detail in conjunction with the drawings.

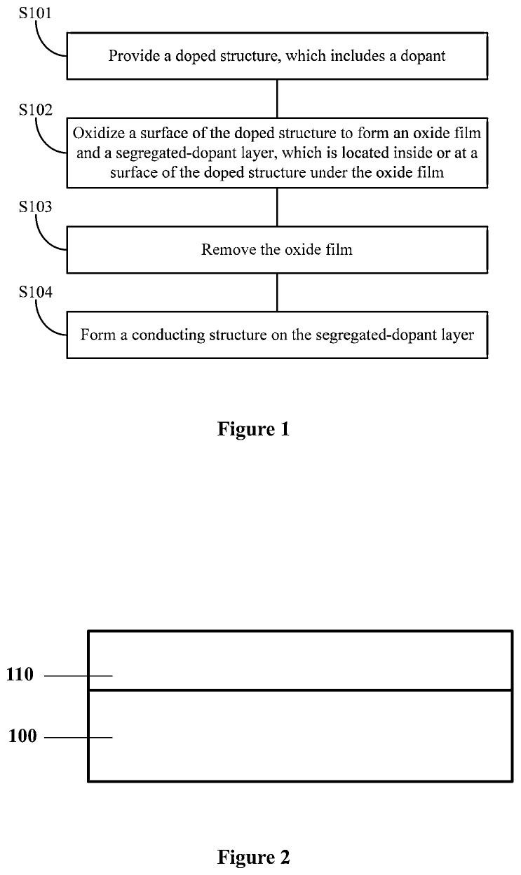

Reference is made to FIG. 1, which is a flow chart of a method for manufacturing a semiconductor according to an embodiment of the present disclosure.

In step S101, a doped structure 110 is provided. The doped structure 110 includes a dopant. Reference is made to FIG. 2.

In an embodiment, the doped structure 110 may be a structure that is to be led out, for example, may be at least one of a source structure, a drain structure, or a gate structure. The doped structure 110 may be obtained by doping an intrinsic semiconductor, and the intrinsic semiconductor may include silicon, germanium or silicon germanium. The doped structure 110 includes the dopant, and the dopant may be an N-type dopant or a P-type dopant. The doped structure 110 is formed through heavy doping. The N-type dopant may include phosphorus (P), arsenic (As), antimony (Sb), or another pentavalent element. The P-type dopant may include boron (B), gallium (Ga), indium (In), or another trivalent element. A doping concentration of the doped structure 110 may range from 10¹⁹ cm⁻³ to 10²² cm⁻³, and a thickness of the doped structure may range from 1 nm to 200 nm.

A substrate 100, or a semiconductor structure on the substrate 100, may be doped to obtain the doped structure 110. The substrate 100 is configured to support the semiconductor structure, and may serve a part of the semiconductor structure. In an embodiment, it is taken as an example for illustration that a silicon substrate 100 is doped to obtain the doped structure 110. Referring to FIG. 2, an upper surface of the substrate 100 is doped through, for example, ion implantation or diffusion, to obtain the doped structure 110 on the substrate 100. As an example, the doped structure 110 in the drawings may be located in a source region, a drain region, or a gate region. Besides the doped structure 110, the semiconductor structure may further include another structure located in another region, which is not illustrated herein.

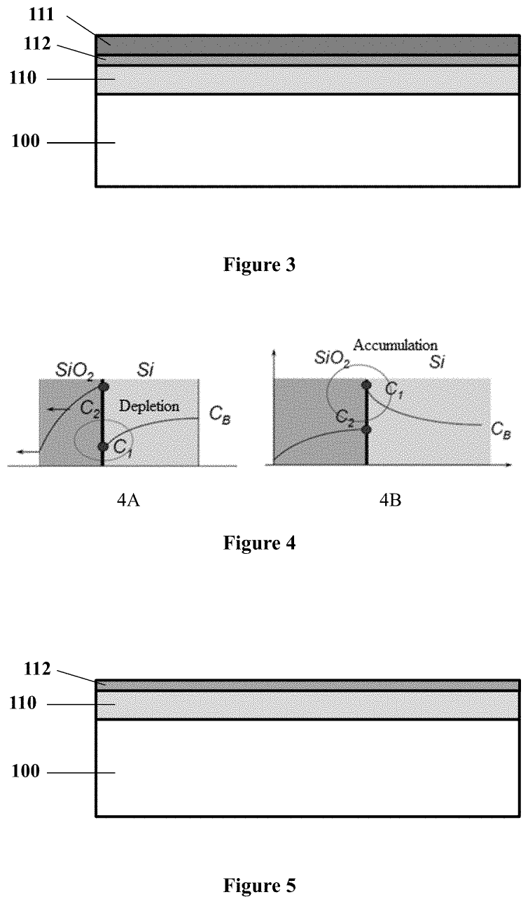

In step S102, a surface of the doped structure 110 is oxidized to form an oxide film 111 and a segregated-dopant layer 112. The segregated-dopant layer 112 is located inside the doped structure under the oxide film 111, or at a surface of the doped structure under the oxide film 111. Reference is made to FIG. 3.

In an embodiment, the surface of the doped structure 110 may be oxidized to form the oxide film 111. Thereby, a thickness of the original doped structure 110 is reduced, and a new doped structure 110 is formed. During the oxidation, the dopant at the interface between the oxide film 111 and the doped structure 110 is redistributed, so that the segregated-dopant layer 112 is formed inside or at the surface of the doped structure 110 under the oxide film. The segregated-dopant layer may be located at a certain depth of the doped structure 110. The depth is small, and may even be zero. Therefore, a range of the depth is not shown in the drawings. Main factors affecting the redistribution of the dopant are includes: (1) a segregation phenomenon of the dopant, (2) escape of the dopant via the surface of the oxide film 111, (3) a rate of the oxidation, and (4) a rate of the dopant diffusing in the oxide film 111.

The segregation phenomenon of the dopant may serve as a basis of redistribution of the dopant at the interface between the doped structure 110 and the oxide film 111. Thereby, the concentration of the dopant is adjusted at the interface between the doped structure 110 and the oxide film 111. During the oxidation, a segregation coefficient may be defined as a ratio of an equilibrium doping concentration in the doped structure 110 at such interface to an equilibrium doping concentration in the oxide film 111 at such interface. In a case of the segregation coefficient less than 1, the dopant in the doped structure 110 escapes slightly in segregation via the interface with the oxide film 111. After redistribution, the doping concentration in the oxide film 111 is higher than that in the doped structure 110, and the doping concentration in the doped structure 110 decreases at a surface close to the oxide film 111. In a case of the segregation coefficient greater than 1, the dopant in the oxide film 111 escapes slightly in segregation during the oxidization, via the interface with the doped structure 110. After redistribution, the doping concentration in the doped structure 110 is higher than that in the oxide film 111, and the doping concentration in the doped structure 110 increases at a surface close to the oxide film 111.

The segregation coefficient is relevant to materials of the doped structure 110, the oxide film 111, and the dopant. In a case that the doped structure 110 is silicon-based (Si-based) and the oxide film 111 is silicon oxide (SiO₂), the segregation coefficient between the doped structure 110 and the oxide film 111 is less than 1 when the dopant is boron (B) or indium (In), and is greater than 1 when the dopant is phosphorus (P), arsenic (As), antimony (Sb), or gallium (Ga). In a case that the material of the doped structure 110 is germanium-based and the oxide film 111 is germanium oxide, the segregation coefficient between the doped structure 110 and the oxide film 111 is less than 1 when the dopant is phosphorus (P), arsenic (As), or antimony (Sb), and is greater than 1 when the dopant is boron (B) or silicon (Si). In a case that the doped structure 110 is made of another material, the dopant may be another element, which is not enumerated herein.

Reference is made to FIG. 4, which is a schematic diagram of a segregation phenomenon according to an embodiment of the present disclosure. The doped structure 110 may be silicon-based and the oxide film 111 may be silicon oxide. In such case, reference is made to FIG. 4A for the segregation coefficient less than 1. The concentration of the dopant is C_{B} inside silicon, the equilibrium concentration of the dopant is C₁ in silicon at the interface, and C₁ is less than C_{B}. The equilibrium concentration of the dopant in SiO₂ at the interface is C₂, and C₂ is greater than C₁. Thus, the dopant at the interface diffuses into SiO₂ from silicon during the oxidation, and the dopant in silicon depletes. Reference is made to FIG. 4B for the segregation coefficient greater than 1. The concentration of the dopant is C_{B} inside silicon, the equilibrium concentration of the dopant is C₁ in silicon at an interface, and C₁ is greater than C_{B}. Thus, the dopant diffuses from SiO₂ toward the interface during the oxidation that forms SiO₂, and the concentration of the dopant increases at the interface. The equilibrium concentration of the dopant in SiO₂ at the interface is C₂, and C₂ is less than C₁. The dopant in silicon accumulates.

That is, during oxidizing the surface of the doped structure 110, the doping concentration at the interface between the oxide film 111 and the doped structure 110 under the oxide film 111 can be increased by selecting a dopant rendering the segregation coefficient greater than 1. Such region with the high doping concentration serves the segregated-dopant layer 112, and the concentration of dopant in the segregated-dopant layer 112 is higher than that in other regions of the doped structure 110. Thereby, a structure with a high surface doping concentration can be obtained without an additional doping process. The dopant may be a material that diffuses slowly in the oxide film 111, so as to facilitate increasing the doping concentration at the interface of the doped structure 110 that is close to the oxide film 111.

A thickness of the oxide film 111 may range from 0.5 nm to 50 nm. The oxidation may include ozone (O₃) oxidation, thermal oxidation, steam oxidation, or the like.

The segregated-dopant layer 112 is formed along with the oxide film 111. The dopant in the segregated-dopant layer 112 may be activated through annealing treatment, so as to prevent the dopant in the segregated-dopant layer 112 from staying inactive. In such case, the oxide film 111 may serve as a capping layer, and the annealing treatment may be rapid thermal annealing (RTP), microwave annealing, laser annealing, or the like. It is appreciated that the annealing treatment may be omitted to prevent increasing the junction depth. Further, the annealing treatment may be performed during the oxidation to reduce time consumption. In such case, the dopant inside the segregated-dopant layer is activated when the segregated-dopant layer being formed.

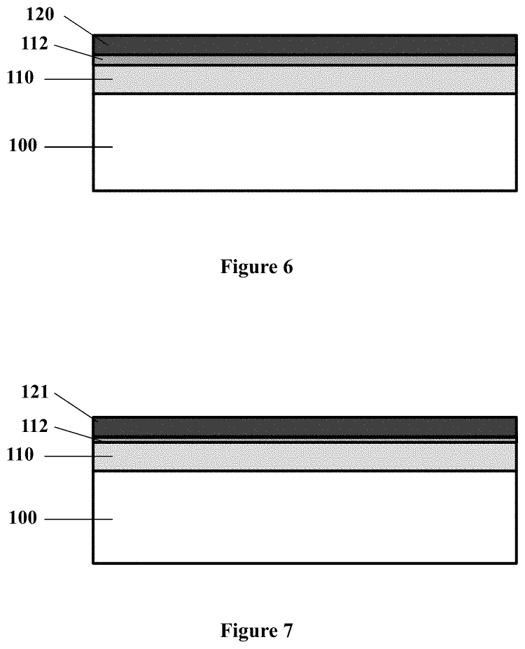

In step S103, the oxide film 111 is removed. Reference is made to FIG. 5.

The segregated-dopant layer 112 is formed when the oxide film 111 being formed. The concentration of the dopant is higher in the segregated-dopant layer 112 than in other regions of the doped structure 110, so that a structure with a high surface doping concentration can be obtained without an additional doping process. Afterwards, the oxide film 111 may be removed. Thereby, the segregated-dopant layer 112 in the doped structure 110 is exposed, and the structure with the high surface doping concentration is obtained.

The oxide film 111 may be removed through anisotropic dry etching or another process.

In step S104, a conducting structure 121 is formed on the segregated-dopant layer 112. Reference is made to FIG. 6 and FIG. 7.

After the segregated-dopant layer 112 exposed, the conducting structure 121 may be formed on the segregated-dopant layer 112. An ohmic contact is formed between the segregated-dopant layer 112 and the conducting structure. The segregated-dopant layer 112 has a high doping concentration, which increases a probability of carriers tunneling across the metal/semiconductor interface. Hence, a contact resistance is reduced, that is, the contact resistance is small between the segregated-dopant layer 112 and the conducting structure 121. The conducting structure may be a metal material, or a compound yielded from reaction between a metal material and the doped structure 110.

In a specific embodiment, the conducting material 120 may be formed on the doped structure 110, as shown in FIG. 6. The conducting material 120 may be metal. In a case that the conducting structure is the metal material, the conducting structure has been formed on the segregated-dopant layer 112 at such time. In a case that the conducting structure 121 is the compound yielded from reaction the metal material 120 and the doped structure 110, the doped structure 110 and the conducting material 120 may be annealed for reaction. Thereby, the compound serving as the conducting structure 121 is generated on the doped structure 110, as shown in FIG. 7.

The conducting material includes at least one of Ni, Pt, NiPt, Co, Ti, Ta, W, Ru, Cu, CoTi, TaN, or TiN. The NiPt may be an alloy in which a concentration of Pt ranges from 5% to 30% Pt, and CoTi may be an alloy in which a concentration of Ti ranges from 5% to 40%. A thickness of the oxide film may range from 1 nm to 100 nm. In a case that the material of the doped structure 110 includes Si, the compound yielded from reaction includes a silicide of the metal material. In a case that the material of the doped structure 110 includes germanium, the compound yielded from reaction includes a germanide of the metal material.

There may be unreacted conducting material (not shown in the figure) remaining on the compound, after the conducting structure 121 including the compound is formed. In such case, the unreacted conducting material may be removed, and then the conducting structure 121 is subject to a metal-interconnecting process. Alternatively, the unreacted conducting material may be retained, and then the unreacted conducting material on the conducting structure 121 is subject to a metal-interconnecting process.

The method for manufacturing the semiconductor structure is provided according to embodiments of the present disclosure. The doped structure is provided, where the doped structure may include a dopant. The surface of the doped structure is oxidized to form the oxide film. In such case, the dopant at the interface between the oxide film and the doped structure may be redistributed, and thereby the segregated-dopant layer is formed inside or at a surface of the doped structure under the oxide film. The concentration of the dopant is higher in the segregated-dopant layer than in other regions of the doped structure. After the oxide film is removed, the doped structure with a high surface doping concentration can be obtained without an additional doping process. Therefore, after the conducting structure is formed on the segregated-dopant layer, a low contact resistance between the conducting structure and the doped structure is obtained, and a device performance is improved.

A semiconductor structure is further provided according to an embodiment of the present disclosure. The semiconductor structure includes a doped structure and a conducting structure.

The doped structure includes a dopant. A segregated-dopant layer is formed inside or at a surface of the doped structure. A concentration of the dopant is higher in the segregated-dopant layer than in other regions of the doped structure

The conducting structure is located on the segregated-dopant layer.

In an optional embodiment, the conducting structure is a compound yielded from reaction between the doped structure and a conducting material.

In an optional embodiment, a material of the doped structure includes Si, SiGe, or Ge.

The doped structure, the segregated-dopant layer, and the conducting structure can be referred to the description of the method embodiments and are not described repeatedly here.

In an optional embodiment, the conducting material includes at least one of Ni, Pt, NiPt, Co, Ti, Ta, W, Ru, Cu, CoTi, TaN, or TiN.

A transistor is further provided according to an embodiment of the present disclosure. The transistor is formed on a semiconductor substrate, and includes a gate structure, a source structure, and a drain structure. The transistor includes the forgoing semiconductor structure, of which the doped structure serves as at least one of the source structure, the drain structure, or the gate structure.

In an optional embodiment, the transistor is a MOSFET, a FinFET, or a GAAFET.

In an optional embodiment, the gate structure is located on the semiconductor substrate.

Alternatively, the semiconductor substrate includes a protruding structure, and the gate structure covers a top surface and two sidewalls of the protruding structure.

Alternatively, a nanowire that is horizontal or vertical is provided on the semiconductor substrate, the gate structure surrounds the nanowire, and the source structure and the drain structure are located at two ends, respectively, of the nanowire.

In an optional embodiment, the conducting structure includes a contacting region. The contacting region is configured to contact another conducting member for leading out the conducting structure.

The foregoing embodiments are only preferred embodiments of the present disclosure. The preferred embodiments according to the disclosure are disclosed above, and are not intended to limit the present disclosure. Those skilled in the art can make some variations and improvements to the technical solutions of the present disclosure, or make some equivalent variations on the embodiments without departing from the scope of technical solutions of the present disclosure. All simple modifications, equivalent variations and improvements made based on the technical essence of the present disclosure without departing the content of the technical solutions of the present disclosure fall within the protection scope of the technical solutions of the present disclosure.

1. A method for manufacturing a semiconductor, comprising:
providing a doped structure, wherein the doped structure comprises a dopant;
forming a segregated-dopant layer inside or at a surface of the doped structure, wherein a concentration of the dopant is higher in the segregated-dopant layer than in the doped structure; and
forming a conducting structure on the segregated-dopant layer.

2. The method according to claim 1, wherein forming the segregated-dopant layer comprises:
oxidizing a surface of the doped structure, to form an oxide film and the segregated-dopant layer, wherein the concentration of the dopant is higher in the segregated-dopant layer than in the doped structure that is not oxidized and the oxide film; and
removing the oxide film.

3. The method according to claim 1, wherein forming the conducting structure on the segregated-dopant layer comprises:
forming a conducting material on the doped structure, and
annealing the doped structure and the conducting material, wherein the doped structure and the conducting material react in the annealing to yield a compound serving as the conducting structure.

4. The method according to claim 3, wherein the conducting material comprises at least one of Ni, Pt, NiPt, Co, Ti, Ta, W, Ru, Cu, CoTi, TaN, or TiN.

5. The method according to claim 2, wherein before removing the oxide film, the method further comprises:
activating the dopant in the segregated-dopant layer through annealing treatment, after the oxide film being formed or during the oxidizing.

6. The method according to claim 5, wherein the annealing treatment comprises rapid thermal annealing, microwave annealing, or laser annealing.

7. The method according to claim 1, wherein the doped structure is at least one of a source structure, a drain structure, or a gate structure.

8. The method according to claim 1, wherein a material of the doped structure comprises Si, SiGe, or Ge.

9. The method according to claim 1, wherein a thickness of the oxide film ranges from 0.5 nm to 50 nm.

10. A semiconductor structure, comprising:
a doped structure, wherein the doped structure comprises a dopant;
a segregated-dopant layer, located inside or at a surface of the doped structure, wherein a concentration of the dopant is higher in the segregated-dopant layer than in the doped structure; and
a conducting structure, located on the segregated-dopant layer.

11. The structure according to claim 10, wherein the conducting structure is a compound capable to be yielded from reaction between the doped structure and a conducting material.

12. The structure according to claim 10, wherein the conducting material comprises at least one of Ni, Pt, NiPt, Co, Ti, Ta, W, Ru, Cu, CoTi, TaN, or TiN.

13. A transistor, formed on a semiconductor substrate, wherein the transistor comprises a gate structure, a source structure, and a drain structure, and wherein the transistor comprises the semiconductor structure according to claim 9, and the doped structure serves as at least one of the source structure, the drain structure, and the gate structure.

14. The transistor according to claim 13, wherein the transistor is a MOSFET, a FinFET, or a GAAFET.

15. The transistor according to claim 13, wherein:
the gate structure is located on the semiconductor substrate.

16. The transistor according to claim 13, wherein:
the semiconductor substrate comprises a protruding structure, and the gate structure covers a top surface and two sidewalls of the protruding structure.

17. The transistor according to claim 13, wherein:
a nanowire that is horizontal or vertical is provided on the semiconductor substrate, the gate structure surrounds the nanowire, and the source structure and the drain structure are located at two ends, respectively, of the nanowire.

18. The transistor according to claim 13, further comprising:
a contacting region, configured to contact a conducting member for leading out the conducting structure.
